(19) United States
(12) Patent Application Publication
(10) Pub. No.: US 2026/0010065 A1
(43) Pub. Date: Jan. 8, 2026

(54) BLANK MASK AND PHOTOMASK

(71) Applicant: LG INNOTEK CO., LTD., Seoul (KR)

(72) Inventors: Heun PARK, Seoul (KR); Kab Young KIM, Seoul (KR); Hae Rok SON, Seoul (KR)

(21) Appl. No.: 18/992,369

(22) PCT Filed: Jun. 14, 2023
(86) PCT No.: PCT/KR2023/008223

§ 371 Date: Jan. 8, 2025

(30) Foreign Application Priority Data
Jul. 8, 2022 (KR) 10-2022-0084580

(51) Int. Cl. G03F 1/46

(52) U.S. Cl. CPC G03F 1/46

(57) ABSTRACT

A blank mask according to an embodiment includes a substrate; and a conductive layer disposed on the substrate, the conductive layer includes a first layer and a second layer having different electrical conductivities, and the electrical conductivity of the conductive layer is 500 S/cm to 2000 S/cm.

### TECHNICAL FIELD

The embodiment relates a blank mask and a photomask.

### BACKGROUND ART

Semiconductor integrated circuit (Large Scale Integration: LSI) devices or flat panel display (Flat Panel Display: FPD) devices are manufactured by a photolithography process that transfers a pattern using a photomask.

The blank mask has a structure in which a metal film or a metal compound film including a metal material and a photoresist film are formed on a transparent substrate including synthetic quartz glass. The photomask includes a metal pattern or a metal compound pattern formed by patterning a thin film of the blank mask.

The thin film includes a light-shielding film, an anti-reflection film, a phase-shift film, a semi-transmissive film, or a reflective film according to required optical characteristics. The blank mask includes at least one or more of the thin films, and the thin films are patterned into a required shape to manufacture a photomask including a transfer pattern.

Meanwhile, the photomask transfers a pattern through a contact or non-contact photolithography process. As a result, a structure constituting a device can be formed on a substrate to be transferred.

At this time, as the number of times a photomask is repeatedly used in a photolithography process increases, electrostatic charges charged to the photomask accumulate, and when a charge difference between the patterns exceeds a breakdown voltage, static electricity is generated between the patterns, damaging the pattern of the photomask. In particular, the more isolated a pattern is, the higher the potential difference with respect to the adjacent pattern, so more damage occurs due to electrostatic discharge current. In particular, isolated patterns have a higher potential difference with respect to adjacent patterns, and therefore are more susceptible to damage from electrostatic discharge current. This causes a problem in that the photomask with the damaged pattern must be modified or discarded.

Therefore, a new structure of a photomask that can reduce the electrostatic discharge current of the photomask as described above is required.

### DISCLOSURE

### Technical Problem

The embodiment provides a photomask capable of reducing discharge current generated by static electricity of a pattern and increasing discharge voltage.

### Technical Problem

A blank mask according to an embodiment comprises a substrate; and a conductive layer disposed on the substrate, the conductive layer includes a first layer and a second layer having different electrical conductivities, and the electrical conductivity of the conductive layer is 500 S/cm to 2000 S/cm.

### Advantageous Effects

A blank mask according to the embodiment includes a conductive layer having a conductivity of a set range. Accordingly, a photomask manufactured by the blank mask is formed into a pattern having an electrical conductivity of a set range.

Accordingly, a discharge voltage of the pattern of the photomask increases. In addition, when static electricity occurs between adjacent patterns, an intensity of the discharge current due to static electricity is reduced. Accordingly, a size of a heating temperature due to the discharge current is reduced. Accordingly, the pattern of the photomask can be prevented from being damaged by the heating of the discharge current generated between adjacent patterns.

That is, the electrical conductivity of the conductive layer of the blank mask used to manufacture the photomask is reduced, and the electrical conductivity of the pattern of the photomask manufactured by the blank mask is also reduced.

Accordingly, a current density of the discharge current, which is proportional to a size of the electrical conductivity and a size of the electric field, is reduced. Accordingly, when static electricity occurs between adjacent patterns, the size of the discharge current generated by static electricity is reduced. Accordingly, the size of the heating temperature due to the discharge current is reduced.

Therefore, the blank mask according to the embodiment can manufacture a photomask having improved reliability. In addition, the photomask according to the embodiment can form a circuit pattern having a uniform and fine line width on a wafer by preventing damage to the pattern, and can increase a life of the photomask.

### DESCRIPTION OF DRAWINGS

FIG. 1 is a cross-sectional view of a blank mask according to an embodiment.

FIG. 2 is a drawing showing an enlarged view of region A of FIG. 1.

FIG. 3 is a drawing showing a cross-sectional view of a photo mask according to an embodiment.

FIG. 4 is a drawing for explaining a principle of static electricity generation in a photo mask according to an embodiment.

FIGS. 5 and 6 are drawings for explaining an electrical conductivity of a pattern of a photo mask according to an embodiment and a change in current density according to an electric field (E-field).

FIG. 7 is a graph showing a discharge voltage and a discharge current according to an electrical conductivity of a pattern of a photo mask according to an embodiment and a comparative example.

FIG. 8 is a photograph showing damage to patterns of a photo mask according to an embodiment and a comparative example.

### MODE FOR INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a photomask according to an embodiment will be described with reference to the drawings.

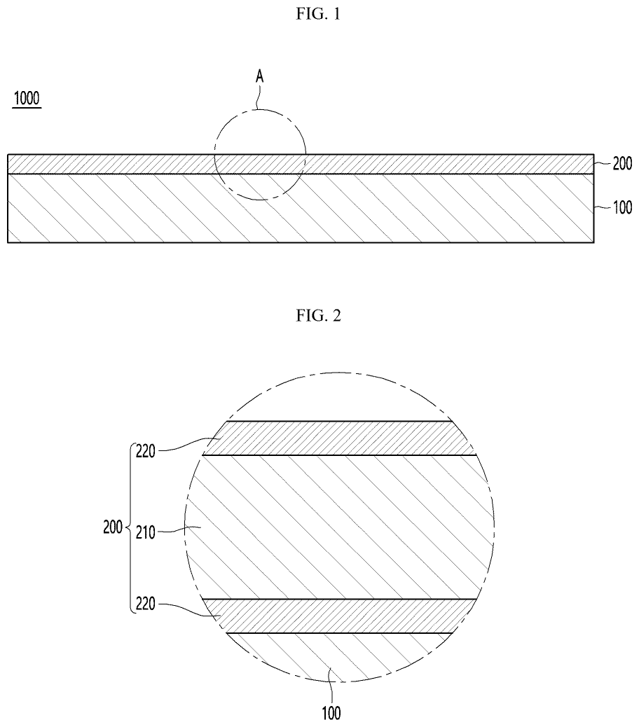

FIG. 1 is a cross-sectional view of a blank mask according to an embodiment.

Referring to FIG. 1, a blank mask 1000 according to an embodiment includes a substrate 100 and a conductive layer 200.

The substrate 100 includes a transparent substrate. For example, the substrate 100 may be a quartz glass, a soda lime, a glass substrate, an alkali-free glass substrate, or a low thermal expansion glass substrate. For example, the substrate 100 includes a quartz substrate.

The conductive layer 200 is disposed on an entire surface of the substrate 100. The conductive layer 200 has an electrical conductivity within a set range. Accordingly, patterns of a photomask manufactured by the blank mask also have an electrical conductivity within a set range. Therefore, damage to patterns of a photomask manufactured by the blank mask can be prevented.

The conductive layer 200 includes a metal. In detail, the conductive layer 200 includes a metal oxide. In detail, the conductive layer 200 includes a chromium oxide. More specifically, the conductive layer 200 includes a chromium oxide including at least one of chromium, carbon, oxygen, and nitrogen. More specifically, the conductive layer 200 includes a chromium oxide including at least one of CrO, CrON, CrCO, and CrCON.

Referring to FIG. 2, the conductive layer 200 includes a plurality of layers. For example, the conductive layer 200 includes a first layer 210 and a second layer 220. In detail, the second layer 220 is disposed on at least one of an upper surface and a lower surface of the first layer 210.

Although FIG. 2 illustrates that the conductive layer 200 is formed in three layers, the embodiment is not limited thereto. The conductive layer 200 is formed in two layers or in four or more layers.

The first layer 210 and the second layer 220 have different compositions. In addition, the first layer 210 and the second layer 220 have different composition ratios. In addition, the first layer 210 and the second layer 220 have different physical properties.

For example, the first layer 210 includes a chromium element, a carbon element, and an oxygen element. In addition, the second layer 220 includes a chromium element, a carbon element, an oxygen element, and a nitrogen element.

In addition, the first layer 210 and the second layer 220 have different oxygen contents. That is, a composition ratio of oxygen in a metal oxide of the first layer 210 and a composition ratio of oxygen in a metal nitride oxide of the second layer 220 are different.

An electrical conductivity of the conductive layer 200 is controlled by controlling an oxygen content of the first layer 210 and the second layer 220.

In addition, the first layer 210 and the second layer 220 have electrical conductivity of different sizes. For example, the electrical conductivity of the first layer 210 is greater than the electrical conductivity of the second layer 220. Alternatively, the electrical conductivity of the second layer 220 is greater than the electrical conductivity of the first layer 210.

In addition, the first layer 210 and the second layer 220 have thicknesses of different sizes. In detail, a thickness of the first layer 210 is greater than a thickness of the second layer 220.

When the blank mask is patterned to form a photomask, the first layer 210 is defined as a light-shielding layer of the photomask. In addition, the second layer 220 is defined as an anti-reflection layer of the photomask.

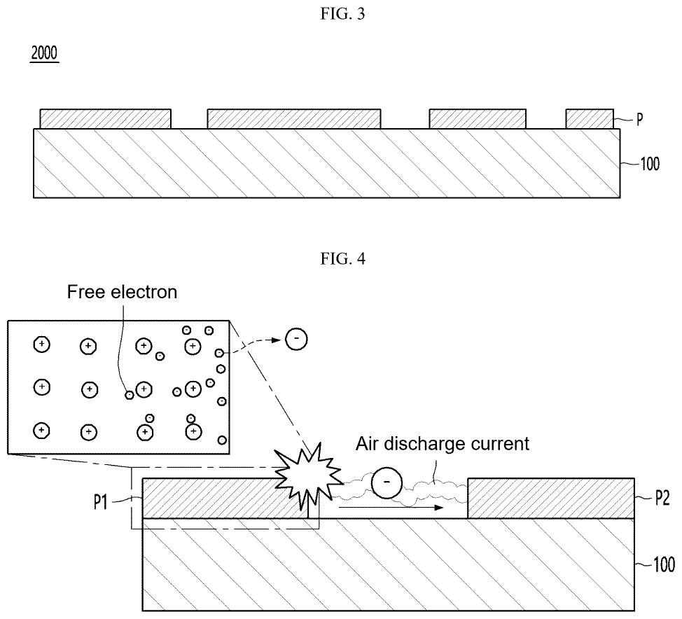

FIG. 3 is a drawing showing a cross-sectional view of a photo mask according to an embodiment.

The photomask 2000 applies a photoresist to the blank mask 1000 and performs exposure and development using an electron beam. That is, the exposure and development process is performed using an electron beam according to desired semiconductor circuit information. Then, after etching the chrome, the photoresist is removed.

Accordingly, the photomask forms a plurality of patterns P having semiconductor circuit information. For example, the photomask 2000 includes a plurality of patterns having set line widths and spacings. In detail, the photomask 2000 includes a plurality of patterns P having a line width of more than 0 μm to less than 20 μm and a spacing of more than 0 μm to less than 20 um.

That is, the photomask 2000 blocks light in a region where the pattern P is formed, and transmits light in the substrate 100 where the pattern is not formed. Accordingly, the photomask is disposed on a wafer, and a circuit pattern of semiconductor circuit information included in the photomask can be formed on a surface of the wafer through exposure, development, and etching processes.

Meanwhile, a plurality of patterns P of the photomask are disposed adjacent to each other with a fine line width. Accordingly, a discharge current can flow between adjacent patterns due to static electricity occurring in the pattern. This discharge current causes heat generation, and damage occurs to the patterns due to this heat generation temperature.

FIG. 4 is a drawing for explaining a principle of static electricity generation in a photo mask according to an embodiment.

Referring to FIG. 4, a plurality of patterns are disposed on the substrate 100. For example, a first pattern P1 and a second pattern P2 having circuit information and adjacent to each other are disposed on the substrate 100.

In the photomask, electrostatic charges are accumulated in each pattern P1 and P2 during a manufacturing process or a handling process. As a result, free electrons according to the electrostatic charges are emitted from the first pattern P1 or the second pattern P2. At this time, when an air between the patterns reaches an insulation breakdown strength, the air between the patterns becomes a conductor and becomes a conductive path. Accordingly, the free electrons emitted from the first pattern P1 or the second pattern P2 move. For example, the free electrons emitted from the first pattern P1 move to the second pattern P2 along the conductive path. As a result, a conductive path is formed between the first pattern P1 and the second pattern P2, and current flows along the conductive path. This phenomenon is defined as a discharge of the pattern, and the current flowing along the path is defined as a discharge current. In addition, a voltage at which discharge current is generated by static electricity is defined as a discharge voltage.

The discharge current causes heat generation. This heat generation temperature is proportional to the discharge current. Therefore, as the size of the discharge current increases, a heat generation temperature also increases. That is, as the discharge current between the first pattern P1 and the second pattern P2 increases, the heat generation temperature between the first pattern P1 and the second pattern P2 also increases. Therefore, as the heat generation temperature increases, the first pattern P1 and the second pattern P2 may be damaged.

Accordingly, the patterns of the photomask are damaged. Accordingly, when forming a circuit pattern on a wafer using the photomask, an accurate circuit pattern cannot be formed on the wafer. In addition, when forming a circuit pattern on a wafer, a line width of the circuit pattern may become uneven.

The discharge current generated between the first pattern P1 and the second pattern P2 is proportional to a current density (J) of the first pattern P1 and the second pattern P2. In addition, the current density (J) is proportional to an electrical conductivity (G) and an electric field (e-field, E). In detail, the current density (J) is defined by a following formula.

$$Current density ( J ) = electrical conductivity ( σ ) * electric field ( E - field , E ) \qquad [ Formula ]$$

Therefore, in order to reduce the discharge current occurring between the first pattern P1 and the second pattern P2, the current density (J) must be reduced. In addition, in order to reduce the current density (J), a size of either the electrical conductivity or the electric field must be reduced.

Meanwhile, the size of the electrical conductivity does not affect the electric field.

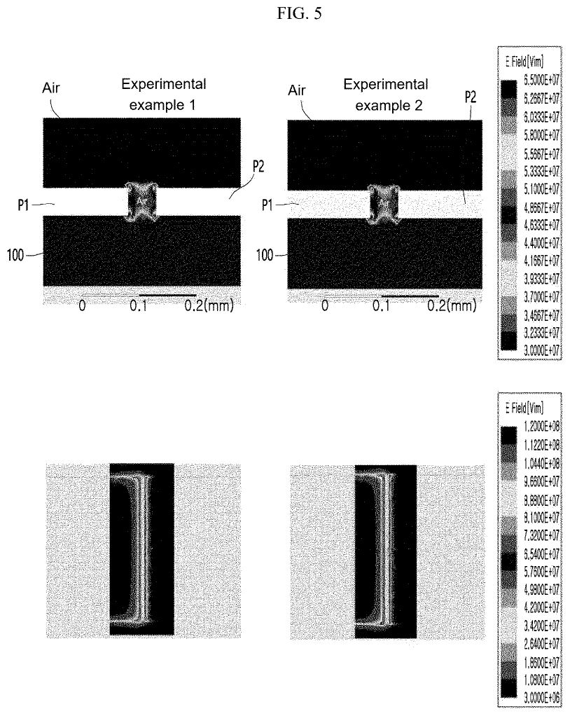

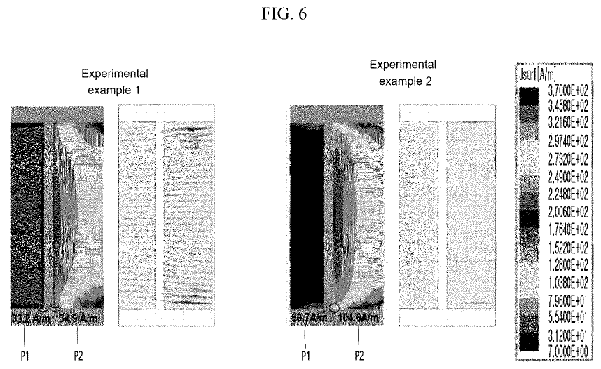

FIGS. 5 and 6 are diagrams for explaining the change in the electric field and the change in the current density when the electrical conductivity is different. FIGS. 5 and 6 are diagrams showing the change in the electric field and the change in the current density in Experimental Examples 1 and 2 where the electrical conductivity is different. Experimental Example 1 is a photomask including a pattern with low electrical conductivity, and Experimental Example 2 is a photomask with relatively higher electrical conductivity than Experimental Example 1.

Referring to FIG. 5, the size of the electric field (E-field) of Experimental Examples 1 and 2 is not related to electrical conductivity. That is, referring to FIG. 5, it can be seen that the electric field sizes in Experimental Examples 1 and 2, which have different electrical conductivities, are almost similar.

On the other hand, referring to FIG. 6, it can be seen that the size of the current density is related to electrical conductivity. Referring to FIG. 6, it can be seen that the current density of the patterns P1 and P2 of Experimental Example 2, which have high electrical conductivity, is greater than the current density of the patterns P1 and P2 of Experimental Example 1, which have low electrical conductivity.

Referring to FIGS. 5 and 6, the size of the electrical conductivity does not affect the size of the electric field, and the electrical conductivity is proportional to the current density. Therefore, if the electrical conductivity of the pattern is reduced, the current density can be reduced. In addition, the size of the discharge current can be reduced by reducing the current density.

Therefore, the photomask 2000 according to the embodiment controls the electrical conductivity of the pattern to a set range. Accordingly, the size of the discharge current generated between the adjacent patterns due to the generation of static electricity is reduced. Therefore, a temperature of the heat generated by the discharge current is reduced, so that damage to the pattern of the photomask can be reduced.

Meanwhile, the electrical conductivity of the pattern is controlled by controlling an oxygen content of the pattern. In detail, it is formed by controlling the oxygen content of the conductive layer 200 of the blank mask. More specifically, it is formed by controlling the oxygen content of the first layer 210 which is a light-shielding layer and/or the second layer 220 which is an anti-reflection layer. For example, an electrical conductivity range of the conductive layer 200 can be set, and an oxygen content can be increased by an amount that can satisfy the electrical conductivity range. The sizes of the electrical conductivity of the first layer 210 and the second layer 220 are inversely proportional to the oxygen content. Therefore, the electrical conductivity of the first layer 210 and the second layer 220 can be reduced by increasing the oxygen content of the first layer 210 and the second layer 220.

Therefore, the electrical conductivity of the conductive layer 200 of the blank mask 1000 according to the embodiment is 500 S/cm or more. In detail, the electrical conductivity of the conductive layer 200 is 500 S/cm to 2000 S/cm. More specifically, the electrical conductivity of the conductive layer 200 is 1200 S/cm to 1600 S/cm.

In addition, the electrical conductivity of the pattern P of the photomask 2000 according to the embodiment is 500 S/cm or more. In detail, the electrical conductivity of the pattern P is 500 S/cm to 2000 S/cm. In more detail, the electrical conductivity of the pattern P is 1200 S/cm to 1600 S/cm.

If the electrical conductivity of the conductive layer 200 and the pattern P is 500 S/cm to 2000 S/cm, the current density of the pattern P decreases. Therefore, when static electricity is generated in the pattern P, the size of the discharge current generated between the patterns P is reduced. Therefore, when static electricity is generated, damage to the patterns P can be reduced.

If the electrical conductivity of the conductive layer 200 and the pattern P is less than 500 S/cm, the light-shielding characteristic of the conductive layer 200 and the pattern P decreases. That is, as the oxygen content of the conductive layer 200 and the pattern P increases, a light transmittance of the conductive layer 200 and the pattern P increases. Accordingly, when forming a circuit pattern on a wafer using the photomask, a uniform line width and an accurate circuit pattern cannot be formed. In other words, the characteristics of the photomask are reduced.

In addition, If the electrical conductivity of the conductive layer 200 and the pattern P exceeds 2000 S/cm, the current density of the discharge current increases due to the increase in the electrical conductivity of the pattern P. Accordingly, the heating temperature increases between adjacent patterns, and cracks or other damage may occur in the patterns. Accordingly, when forming a circuit pattern on a wafer using the photo mask, a uniform line width and an accurate circuit pattern cannot be formed. In other words, the characteristics of the photo mask are reduced.

In addition, the discharge voltage of the pattern P of the photo mask 2000 according to the embodiment is 400 V or higher. In detail, the discharge voltage of the pattern P is 400 V to 550 V. In addition, the discharge current of the pattern P of the photo mask 2000 according to the embodiment is 0.5 mA or higher. In detail, the discharge current of the pattern P is 0.5 mA to 2 mA.

Since the pattern P has the electrical conductivity range described above, the size of the discharge voltage that generates static electricity in the pattern P increases, and the size of the discharge current decreases. Therefore, since the size of the discharge voltage of the pattern P increases, the generation of static electricity that may occur in the pattern P decreases. In addition, since the size of the discharge current of the pattern P decreases, when static electricity that may occur in the pattern P is generated, damage to the pattern can be reduced.

Hereinafter, the present invention will be described in more detail through the discharge voltage and discharge current according to the electrical conductivity of the pattern of the photomask according to the embodiments and comparative examples. These examples are merely presented as examples in order to explain the present invention in more detail. Therefore, the present invention is not limited to these examples.

### Embodiment 1

A quartz substrate is prepared. Next, a conductive layer is formed on the quartz substrate.

The conductive layer is formed by stacking at least one first layer and at least one second layer on the quartz substrate. The first layer includes chromium oxide including chromium, oxygen, and carbon. In addition, the second layer includes chromium nitride containing chromium, oxygen, carbon, and nitrogen.

Subsequently, the electrical conductivity of the conductive layer is controlled by controlling an oxygen content of the first layer and/or the second layer. As a result, a conductive layer having an (average) electrical conductivity of 1399 S/cm was formed.

Subsequently, the conductive layer was patterned to manufacture a photomask.

Subsequently, a discharge current and a discharge voltage were measured between the patterns of the photomask.

### Embodiment 2

A conductive layer was formed in a same manner as in the embodiment 1. As a result, a conductive layer having an (average) electrical conductivity of 1274 S/cm was formed.

Subsequently, the conductive layer was patterned to manufacture a photomask.

Subsequently, the discharge current and the discharge voltage were measured between the patterns of the photomask.

### Comparative Example 1

A conductive layer was formed in the same manner as in the embodiment 1. As a result, a conductive layer having an (average) electrical conductivity of 16700 S/cm was formed.

Next, the conductive layer was patterned to manufacture a photomask.

Next, the discharge current and the discharge voltage were measured between the patterns of the photomask.

### Comparative Example 2

A conductive layer was formed in the same manner as in the embodiment 1. As a result, a conductive layer having an (average) electrical conductivity of 2690 S/cm was formed.

Next, the conductive layer was patterned to manufacture a photomask.

Next, the discharge current and the discharge voltage were measured between the patterns of the photomask.

TABLE 1

| | Embodiment 1 | Embodiment 2 |
|---|---|---|
| Electrical Conductivity (S/cm) | 1399 | 1274 |
| Optical Density (450 nm) | 3.11 | 3.17 |
| Etching Rate (s) | 552 | 546 |
| Etching Deviation (nm) | 150.08 | 143.06 |

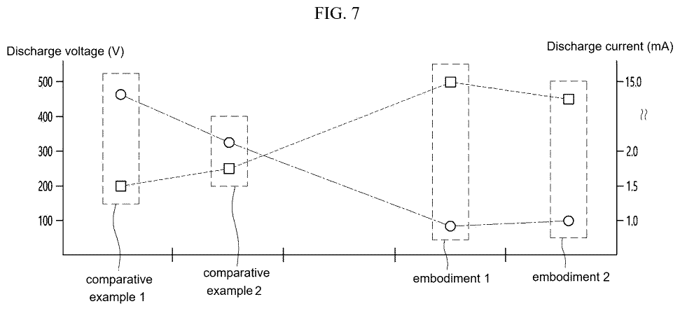

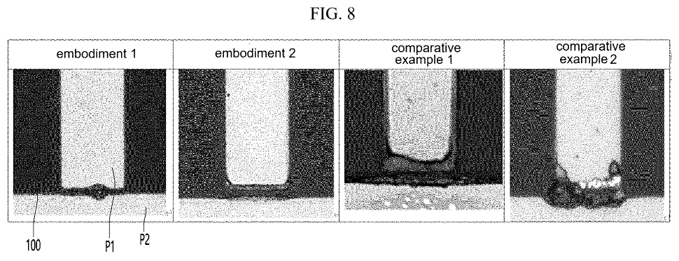

FIG. 7 is a graph showing the discharge voltage and discharge current of the patterns according to the embodiments and comparative examples.

Referring to FIG. 7, the discharge voltage of the patterns according to the embodiments 1 and 2 is greater than the discharge voltage of the comparative examples. Specifically, the discharge voltage of the pattern according to the embodiments 1 is 500 V, the discharge voltage of the pattern according to the embodiments 2 is 450 V, the discharge voltage of the pattern according to the comparative example 1 is 200 V, and the discharge voltage of the pattern according to the comparative example 2 is 250 V.

Therefore, the patterns according to the embodiments 1 and 2 have a large work function, which is the minimum energy for generating static electricity, so that discharge occurs at a high voltage. That is, the discharge voltage is large.

In addition, the discharge current of the patterns according to the embodiments 1 and 2 is smaller than the discharge current of the comparative examples. In detail, the discharge current of the pattern according to the embodiment is 0.9 mA, the discharge current of the pattern according to the embodiment 2 is 1.02 mA, the discharge current of the pattern according to the comparative example 1 is 12.69 mA, and the discharge current of the pattern according to the comparative example 2 is 2.5 mA.

That is, the patterns according to the embodiment 1 and the embodiment 2 have small electrical conductivity. Therefore, the patterns according to the embodiment 1 and the embodiment 2 have small current densities. Accordingly, the size of the discharge current flowing between the patterns is also small.

Therefore, since the patterns according to the embodiment 1 and the embodiment 2 have small discharge currents, the size of the heat generation temperature generated between the patterns is reduced when static electricity is generated.

FIG. 8 is an optical image showing damage to the pattern of the photo mask according to the embodiment and the comparative example when static electricity is generated.

Referring to FIG. 8, in the photo masks according to the embodiment 1 and the embodiment 2, when static electricity is generated in the pattern, since the size of the discharge current flowing between the patterns is small, deformation of the patterns occurs only in a local region, and a degree of deformation of the patterns is not large.

On the other hand, in the photo masks according to the comparative examples 1 and 2, when static electricity is generated in the pattern, since the size of the discharge current flowing between the patterns is large, deformation of the patterns occurs in a large region, and the degree of deformation of the patterns is large.

That is, in the photo masks according to the embodiment 1 and the embodiment 2, the discharge voltage of the pattern having the electrical conductivity of the set range is high, and the discharge current is small. Therefore, when static electricity is generated in the pattern, and the discharge current flows between the patterns, the heat generation temperature caused by this is reduced. Accordingly, the patterns can be prevented from being damaged by the heat generation temperature generated between the patterns. Therefore, the photo masks according to the embodiment has improved reliability and can improve a service life.

In addition, referring to Table 1, the patterns according to the embodiment 1 and the embodiment 2 have an optical density of 3 or more in a wavelength range of 450 nm. Therefore, the patterns according to the embodiment 1 and the embodiment 2 have improved light-shielding characteristics.

In addition, the pattern according to the embodiment has an etching speed of 600 seconds or less. In addition, the pattern according to the embodiment has an etching deviation of 200 nm or less. Here, the etching deviation is defined as a deviation from the line width of the pattern to be set. Therefore, the photomask according to the embodiment includes a pattern having a fine line width and improved etching characteristics.

Therefore, the photomask according to the embodiment can improve the line width and uniformity of the pattern, and reduce the size of the discharge current generated by static electricity between adjacent patterns.

Accordingly, a circuit pattern having a uniform and fine line width can be formed on a wafer by the photomask according to the embodiment, and the service life and reliability of the photomask can be improved.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. In addition, the differences related to these modifications and applications should be interpreted as being included in the scope of the embodiments set forth in the appended claims.

1. A blank mask comprising:
a substrate; and
a conductive layer disposed on the substrate,
wherein the conductive layer includes a first layer and a second layer having different electrical conductivities, and
wherein the electrical conductivity of the conductive layer is 500 S/cm to 2000 S/cm.

2. The blank mask of claim 1, wherein the electrical conductivity of the conductive layer is 1200 S/cm to 1600 S/cm.

3. The blank mask of claim 1, wherein the first layer includes a metal oxide containing a chromium element, a carbon element, and an oxygen element, and
wherein the second layer includes a metal nitride oxide containing a chromium element, a carbon element, an oxygen element, and a nitrogen element.

4. A photomask comprising:
a substrate; and
a plurality of patterns disposed on the substrate,
wherein the pattern includes a first layer and a second layer having different electrical conductivities, and
wherein the electrical conductivity of the pattern is 500 S/cm to 2000 S/cm.

5. The photomask of claim 4, wherein the electrical conductivity of the pattern is 1200 S/cm to 1600 S/cm.

6. The photomask of claim 4, wherein a discharge voltage of the pattern is 400 V to 550 V.

7. The photomask of claim 4, wherein a discharge current of the pattern is 0.5 mA to 2 mA.

8. The photomask of claim 4, wherein an oxygen content of the first layer and an oxygen content of the second layer are different.

9. The photomask of claim 4, wherein the electrical conductivity of the first layer and the electrical conductivity of the second layer are different.

10. The photomask of claim 4, wherein a thickness of the first layer is greater than a thickness of the second layer.

11. The blank mask of claim 1, wherein each of the first layer and the second layer includes an oxide, and
wherein an oxygen content of the first layer and an oxygen content of the second layer are different from each other.

12. The blank mask of claim 1, wherein a thickness of the first layer is greater than a thickness of the second layer.

13. The blank mask of claim 1, wherein the first layer includes a first portion disposed between the substrate and the second layer, and a second portion disposed on the second layer.

14. The blank mask of claim 1, wherein a discharge voltage of the conductive layer including the first layer and the second layer is 400 V to 550 V.

15. The blank mask of claim 1, wherein a discharge current of the conductive layer including the first layer and the second layer is 0.5 mA to 2 mA.

16. The blank mask of claim 1, wherein the first layer is a light-shielding layer, and
wherein the second layer is an anti-reflection layer.

17. The photomask of claim 4, wherein the first layer is a light-shielding layer, and
wherein the second layer is an anti-reflection layer.

18. The photomask of claim 8, wherein the first layer includes a first portion disposed between the substrate and the second layer, and a second portion disposed on the second layer.
